(19) United States
(12) Patent Application Publication
(10) Pub. No.: US 2026/0129899 A1
(43) Pub. Date: May 7, 2026

(54) SEMICONDUCTOR DEVICE

(71) Applicant: Samsung Electronics Co., Ltd., Suwon-si (KR)

(72) Inventors: Sangmoon Lee, Suwon-si (KR); Bongjin Kuh, Suwon-si (KR); Soyeong Ahn, Suwon-si (KR); Suk Yang, Suwon-si (KR)

(21) Appl. No.: 19/335,540

(22) Filed: Sep. 22, 2025

(30) Foreign Application Priority Data
Nov. 7, 2024 (KR) 10-2024-0157252

(51) Int. Cl. H10D 30/47; H10D 30/01

(52) U.S. Cl. CPC H10D 30/481; H10D 30/017

(57) ABSTRACT

Provided is a semiconductor device including a plurality of active patterns spaced apart in a first direction intersecting with a surface of a substrate, a gate electrode extending in a second direction intersecting with the first direction and surrounding the plurality of active patterns, and a source/drain pattern spaced apart from the gate electrode in a third direction intersecting with the first direction and the second direction and connected to the plurality of active patterns in the third direction, and each of the plurality of active patterns includes a contact part, at least a portion of which is inserted within the source/drain pattern, and a connection part extending from the contact part away from the source/drain pattern in the third direction.

### CROSS-REFERENCE TO RELATED APPLICATIONS

This application claims the benefit of Korean Patent Application No. 10-2024-0157252, filed on Nov. 7, 2024, in the Korean Intellectual Property Office, the disclosure of which is incorporated herein by reference in its entirety.

### FIELD

The present disclosure relates to a semiconductor device.

### BACKGROUND

As one of the scaling technologies for raising the density of a semiconductor device, a multi-gate transistor has been suggested, in which a silicon body with a fin shape or a nanowire shape is formed on a substrate and gates are formed on a surface of the silicon body. Meanwhile, due to miniaturization of semiconductor devices, an issue with resistance between elements is emerging.

### SUMMARY

An embodiment of the present disclosure provides a semiconductor device in which resistance is alleviated.

Another embodiment of the present disclosure provides a semiconductor device in which reliability is improved.

Example embodiments are not limited to the technical features described above, and other unstated technical features may be made apparent to those skilled in the art from the following description.

According to an embodiment, there is provided a semiconductor device including a plurality of active patterns spaced apart in a first direction intersecting with a surface of a substrate, a gate electrode extending in a second direction intersecting with the first direction and surrounding the plurality of active patterns, and a source/drain pattern spaced apart from the gate electrode in a third direction intersecting with the first direction and the second direction and connected to the plurality of active patterns in the third direction, and each of the plurality of active patterns may include a contact part, at least a portion of which penetrates into the source/drain pattern, and a connection part extending from the contact part away from the source/drain pattern in the third direction.

According to another embodiment, there is provided a semiconductor device including a plurality of active patterns spaced apart in a first direction intersecting with a surface of a substrate, a gate structure that includes a gate electrode extending in a second direction intersecting with the first direction and surrounding the plurality of active patterns and a gate spacer on a side of the gate electrode in a third direction intersecting with the first direction and the second direction, and a source/drain pattern spaced apart from the gate structure in the third direction and connected to the plurality of active patterns in the third direction, and each of the plurality of active patterns may protrude farther toward the source/drain pattern than the gate structure in the third direction and include a multilayer pattern in the third direction.

According to another embodiment, there is provided a semiconductor device including a plurality of active patterns spaced apart in a first direction intersecting with a surface of a substrate, a gate structure that includes a gate electrode extending in a second direction intersecting with the first direction and surrounding the plurality of active patterns and a gate spacer on a side of the gate electrode in a third direction intersecting with the first direction and the second direction, and a source/drain pattern spaced apart from the gate structure in the third direction and connected to the plurality of active patterns in the third direction, and each of the plurality of active patterns may include a contact part in contact with the source/drain pattern in the third direction and a connection part extending from the contact part away from the source/drain pattern in the third direction, and the contact part may protrude farther toward the source/drain pattern than the gate structure in the third direction, and the connection part may include a two-dimensional material, and the contact part and the connection part may respectively include a first transition metal.

Details of example embodiments are included in the detailed description and drawings.

### BRIEF DESCRIPTION OF THE FIGURES

These and/or other embodiments, features, and advantages of the invention will become apparent and more readily appreciated from the following description of example embodiments, taken in conjunction with the accompanying drawings of which:

FIG. 1 is an example diagram showing a schematic layout of a semiconductor device according to some example embodiments;

FIG. 2 is an example diagram showing a cross-section taken along line A-A of FIG. 1;

FIG. 3 is an example enlarged view showing part R of FIG. 2;

FIG. 4 is an example diagram showing a cross-section taken along line B-B of FIG. 1;

FIG. 5 is an example enlarged view showing part R of FIG. 2 to illustrate a semiconductor device according to other example embodiments;

FIG. 6 is an example enlarged view showing part R of FIG. 2 to illustrate a semiconductor device according to some other example embodiments;

FIG. 7 is an example enlarged view showing part R of FIG. 2 to illustrate a semiconductor device according to still other example embodiments;

FIG. 8 is an example diagram showing a cross-section taken along line A-A of FIG. 1 to illustrate a semiconductor device according to yet other example embodiments;

FIG. 9 is an example diagram showing a cross-section taken along line A-A of FIG. 1 to illustrate a semiconductor device according to yet some other example embodiments; and

FIGS. 10 to 24 are example diagrams showing intermediate operations for illustrating a method of manufacturing a semiconductor device according to some example embodiments illustrated in FIG. 2.

### DETAILED DESCRIPTION

Before describing example embodiments in detail, the words and terminologies used in the specification and claims are not to be construed as limited to common or dictionary meanings but construed as meanings and concepts coinciding with the technical idea of the present disclosure under the principle that the inventor(s) may appropriately define the concept of the terms to explain his or her own invention in the best manner. Therefore, the embodiments described in the specification and the configurations illustrated in the drawings are provided by way of example rather than limitation. Accordingly, it should be understood that there may be various equivalents and modification examples that may replace those when this application is filed.

The term “and/or” includes any and all combinations of one or more of the associated listed items. The term “connected” may be used herein to refer to a physical and/or electrical connection. When components or layers are referred to herein as “directly” on, or “in direct contact” or “directly connected,” no intervening components or layers are present. Likewise, when components are “immediately” adjacent to one another, no intervening components may be present. In the following description, a singular expression includes a plural expression unless apparently otherwise defined by context. It should be understood that terms such as “comprise or include” and “form or compose” are intended to indicate the presence of a feature, a number, a step, an operation, an element, a component, or a combination thereof which are described in the specification and not intended to previously exclude the possibility of the presence or addition of one or more other features, numbers, steps, operations, elements, components, or combinations thereof.

In addition, although the terms such as first and second may be used to describe various elements, these elements are not limited by the above terms, and the terms may be used to distinguish one element from another. Within the scope of the present disclosure, a first element may be referred to as a second element, and similarly, a second element may be referred to as a first element. Further, in the accompanying drawings, the shapes and sizes of elements may be exaggerated for clearer description.

It will be understood that spatially relative terms such as “above,” “upper,” “upper portion,” “upper surface,” “below,” “lower,” “lower portion,” “lower surface,” “side surface,” and the like may be denoted by reference numerals and refer to the drawings, except where otherwise indicated. It will be understood that such spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations), and the spatially relative descriptors used herein may be interpreted accordingly.

The drawings regarding a semiconductor device according to some example embodiments illustrate, as examples, a fin field-effect transistor (FinFET) including a channel region with a fin-type pattern shape, a transistor including nanowires or nanosheets, and a multi-bridge channel field effect transistor (MBCFET), but example embodiments are not limited thereto.

The semiconductor device according to some example embodiments may include a tunneling FET, a three-dimensional (3D) transistor, or a vertical FET. The semiconductor device according to some example embodiments may also include a planar transistor. In addition, the present disclosure may be applied to two-dimensional (2D) material-based FETs and a heterostructure thereof. Further, the semiconductor device according to some example embodiments may also include a bipolar junction transistor and a lateral double-diffused metal-oxide-semiconductor (LDMOS) transistor.

Hereinafter, example embodiments of the present disclosure will be described with reference to the accompanying drawings.

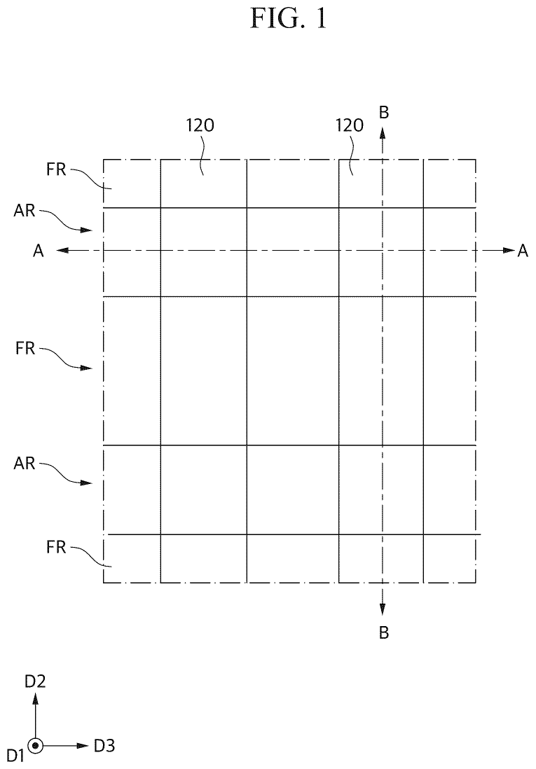

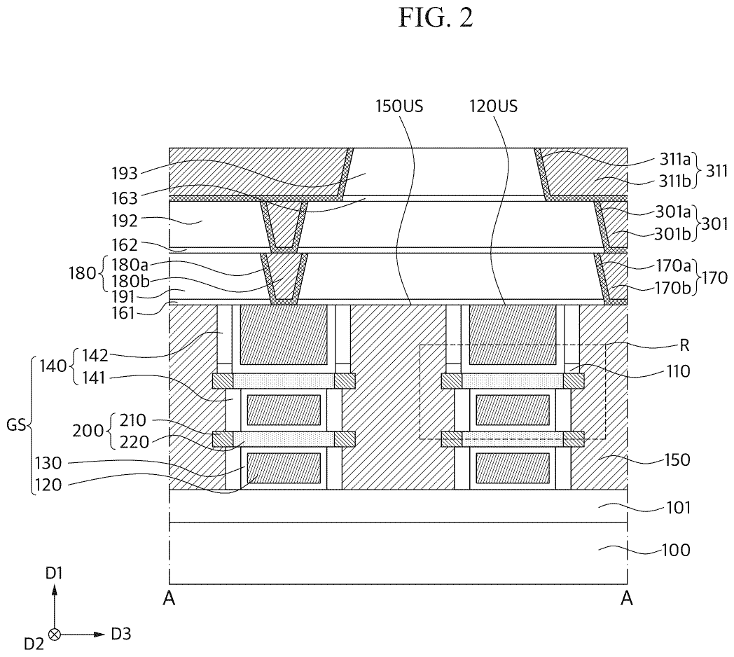

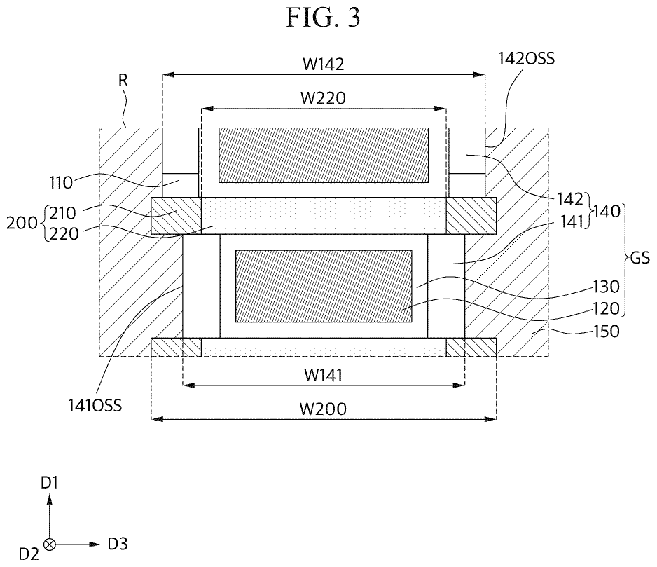

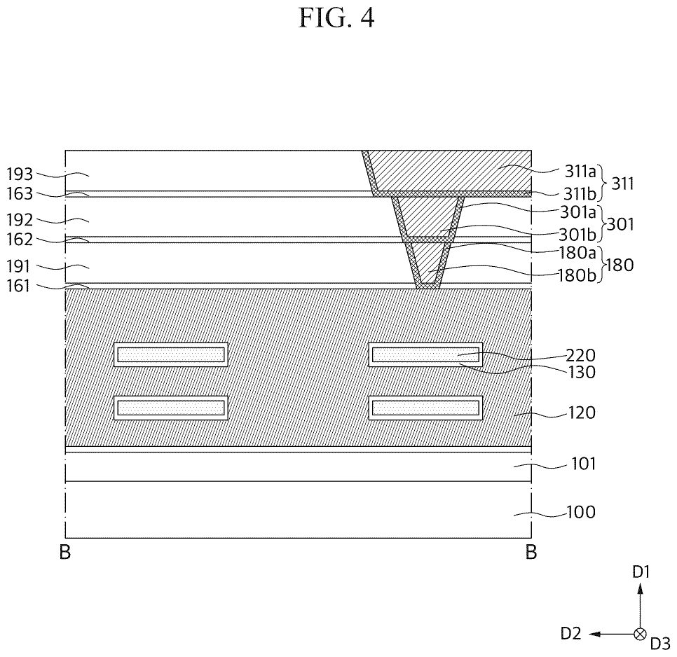

FIG. 1 is an example diagram showing a schematic layout of a semiconductor device according to some example embodiments. FIG. 2 is an example diagram showing a cross-section taken along line A-A of FIG. 1. FIG. 3 is an example enlarged view showing part R of FIG. 2. FIG. 4 is an example diagram showing a cross-section taken along line B-B of FIG. 1.

Referring to FIGS. 1 to 4, the semiconductor device according to some example embodiments may include a substrate 100, a gate structure GS, a first source/drain pattern 150, a plurality of first active patterns 200, a first source/drain contact 170, a first gate contact 180, a first wiring via 301, and a first wiring layer 311.

According to some example embodiments, the substrate 100 may include an active region AR and a field region FR. The active region AR and the field region FR may extend in a third direction D3. The active region AR and the field region FR may be disposed alternately with each other in a second direction D2. For example, the active region AR may be disposed between the field regions FR in the second direction D2. The field region FR may be disposed between the active regions AR in the second direction D2. Each of the second direction D2 and the third direction D3 may refer to a direction being parallel to the substrate 100 and intersecting with a first direction D1. The first direction D1 may refer to a direction perpendicular to the substrate 100. The third direction D3 may refer to a direction in which the active region AR and the field region FR extend. The second direction D2 may refer to a direction in which the active region AR and the field region FR are disposed alternately.

According to some example embodiments, the field region FR may be defined by a trench but is not limited thereto. Although not illustrated, the field region FR may be defined by an insulating layer within a trench formed on the substrate 100. In addition, it is apparent that those of ordinary skill in the art to which the present disclosure pertains may sort each portion into a field region and an active region. The field region FR may have a shallow trench isolation (STI) structure. However, example embodiments are not limited thereto. For example, the field region FR may also be defined by a deep trench.

According to some example embodiments, an element isolation layer may be disposed around the active regions AR spaced apart from each other. In this case, a portion present between two adjacent active regions AR in the element isolation layer may be the field region FR. For example, a portion where a channel region of a transistor that may be one example of the semiconductor device is formed may be an active region, and a portion dividing the channel region of the transistor formed in the active region may be a field region. Alternatively, the active region may be a portion where a fin-type pattern or a nanosheet used as the channel region of the transistor is formed, and the field region may be a portion where the fin-type pattern or the nanosheet used as the channel region is not formed.

According to some example embodiments, the substrate 100 may be bulk silicon or silicon-on-insulator (SOI). In contrast, the substrate 100 may be a silicon substrate or may include other materials, for example, silicon germanium, silicon germanium on insulator (SGOI), indium antimonide, lead telluride, indium arsenide, indium phosphide, gallium arsenide, or gallium antimonide but is not limited thereto.

According to some example embodiments, a first interlayer insulating layer 101 may be disposed on the substrate 100 in the first direction D1. The first interlayer insulating layer 101 may cover an upper surface of the substrate 100. The first interlayer insulating layer 101 may be disposed on the substrate 100 and below the gate structure GS and the first source/drain pattern 150.

According to some example embodiments, the first interlayer insulating layer 101 may include, for example, at least one of silicon oxide, silicon nitride, silicon oxynitride, and a low-permittivity material. For example, the low-permittivity material may include, but is not limited to, fluorinated tetraethyl orthosilicate (FTEOS), hydrogen silsesquioxane (HSQ), bis-benzocyclobutene (BCB), tetramethyl orthosilicate (TMOS), octamethyleyclotetrasiloxane (OMCTS), hexamethyldisiloxane (HMDS), trimethylsilyl borate (TMSB), diacetoxyditertiarybutosiloxane (DADBS), trimethylsilil phosphate (TMSP), polytetrafluoroethylene (PTFE), tonen silazen (TOSZ), fluoride silicate glass (FSG), polyimide nanofoams such as polypropylene oxide, carbon doped silicon oxide (CDO), organo silicate glass (OSG), SiLK, amorphous fluorinated carbon, silica aerogels, silica xerogels, mesoporous silica, or a combination thereof.

According to some example embodiments, the gate structure GS may be disposed on the substrate 100. Each gate structure GS may extend in the second direction D2. The gate structures GS may be disposed to be spaced apart from each other in the third direction D3.

According to some example embodiments, the gate structure GS may be disposed on the plurality of first active patterns 200. For example, the gate structure GS may intersect with the plurality of first active patterns 200. The gate structure GS may surround the plurality of first active patterns 200. Specifically, a gate electrode 120 of the gate structure GS may surround the plurality of first active patterns 200.

The gate electrode 120 of the gate structure GS is illustrated as being disposed across the active region AR and the field region FR in FIG. 1 but is not limited thereto. For example, the gate structure GS may not extend continuously in the second direction D2 across two active regions AR spaced apart in the second direction D2 with the field region FR in between and may be separated in the field region FR. In this case, the gate structure GS extending in the second direction D2 but intersecting with one active region AR and the gate structure GS extending in the second direction D2 but intersecting with another active region AR may be spaced apart from each other in the second direction D2.

According to some example embodiments, the gate structure GS may include the gate electrode 120, a gate insulating layer 130, and a gate spacer 140.

According to some example embodiments, the gate electrode 120 may extend in the second direction D2. The gate electrode 120 may be disposed between the first source/drain patterns 150 adjacent to each other in the third direction D3. The gate electrode 120 may be formed above the substrate 100. The gate electrode 120 may surround the plurality of first active patterns 200. A portion of the gate electrode 120 may be disposed between the plurality of first active patterns 200 adjacent in the first direction D1. A width of the gate electrode 120 in the third direction D3 may be smaller than a width W220 of a first connection part.

According to some example embodiments, the gate electrode 120 may include at least one of metal, metal alloy, conductive metal nitride, metal silicide, doped semiconductor material, conductive metal oxide, and conductive metal oxynitride. For example, the gate electrode 120 may include, but is not limited to, at least one of titanium nitride (TiN), tantalum carbide (TaC), tantalum nitride (TaN), titanium silicon nitride (TiSiN), tantalum silicon nitride (TaSiN), tantalum titanium nitride (TaTiN), titanium aluminum nitride (TiAIN), tantalum aluminum nitride (TaAIN), tungsten nitride (WN), ruthenium (Ru), titanium aluminum (TiAl), titanium aluminum carbonitride (TiAIC-N), titanium aluminum carbide (TiAIC), titanium carbide (TIC), tantalum carbonitride (TaCN), tungsten (W), aluminum (Al), copper (Cu), cobalt (Co), titanium (Ti), tantalum (Ta), nickel (Ni), platinum (Pt), nickel platinum (Ni—Pt), niobium (Nb), niobium nitride (NbN), niobium carbide (NbC), molybdenum (Mo), molybdenum nitride (MoN), molybdenum carbide (MoC), tungsten carbide (WC), rhodium (Rh), palladium (Pd), iridium (Ir), osmium (Os), silver (Ag), gold (Au), zinc (Zn), vanadium (V), and a combination thereof. The conductive metal oxide and the conductive metal oxynitride may include, but are not limited to, an oxidized form of the materials described above.

According to some example embodiments, the gate electrode 120 may be disposed at both sides of the first source/drain pattern 150 to be described below. The gate structure GS may be disposed at both sides of the first source/drain pattern 150 in the third direction D3. As an example, all of the gate electrodes 120 disposed at both sides of the first source/drain pattern 150 may be a functional gate electrode used as a gate of a transistor. As another example, the gate electrode 120 disposed at one side of the first source/drain pattern 150 may be used as the gate of the transistor, while the gate electrode 120 disposed at another side of the first source/drain pattern 150 may be a dummy gate electrode.

According to some example embodiments, the gate insulating layer 130 may extend along an upper surface of the first interlayer insulating layer 101 in the second direction D2. The gate insulating layer 130 may surround the plurality of first active patterns 200. The gate insulating layer 130 may be disposed along a perimeter of the plurality of first active patterns 200. The gate electrode 120 may be disposed on the gate insulating layer 130. The gate insulating layer 130 may be disposed between the gate electrode 120 and the plurality of first active patterns 200. The gate insulating layer 130 may be disposed on an inner side of the gate spacer 140 in the third direction D3 and may surround the gate electrode 120.

According to some example embodiments, a portion of the gate insulating layer 130 may be disposed between the plurality of first active patterns 200 adjacent in the first direction D1 and between the plurality of first active patterns 200 and the first interlayer insulating layer 101 adjacent in the first direction D1.

According to some example embodiments, the gate insulating layer 130 may include silicon oxide, silicon-germanium oxide, germanium oxide, silicon oxynitride, silicon nitride, or a high-permittivity material of which a dielectric constant is greater than that of silicon oxide. The high-permittivity material may include, for example, one or more of boron nitride, hafnium oxide, hafnium silicon oxide, hafnium aluminum oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate.

The gate insulating layer 130 is illustrated as a single layer in FIGS. 2 to 4, which is merely for convenience of description, but is not limited thereto. The gate insulating layer 130 may include a plurality of layers. The gate insulating layer 130 may also include an interfacial layer disposed between the plurality of first active patterns 200 and the gate electrode 120 and a high-permittivity insulating layer.

The semiconductor device according to some example embodiments may include a negative capacitance (NC) FET using a negative capacitor. For example, the gate insulating layer 130 may include a ferroelectric material film having a ferroelectric property and a paraelectric material film having a paraelectric property.

According to some example embodiments, the ferroelectric material film may have negative capacitance, and the paraelectric material film may have positive capacitance. For example, when two or more capacitors are connected in series and a capacitance of each capacitor has a positive value, a total capacitance becomes less than each capacitance of the individual capacitor. In contrast, when at least one of capacitances of two or more capacitors connected in series has a negative value, a total capacitance may have a positive value and be greater than an absolute value of each individual capacitance.

According to some example embodiments, when the ferroelectric material film with negative capacitance and the paraelectric material film with positive capacitance are connected in series, a total capacitance value of the ferroelectric material film and the paraelectric material film connected in series may increase. Using the increasing total capacitance value, a transistor including the ferroelectric material film may have a subthreshold swing (SS) less than 60 millivolts/decade (mV/decade) at room temperature.

According to some example embodiments, the ferroelectric material film may have the ferroelectric property. The ferroelectric material film may include, for example, at least one of hafnium oxide, hafnium zirconium oxide, barium strontium titanium oxide, barium titanium oxide, and lead zirconium titanium oxide. Here, as an example, hafnium zirconium oxide may be a material doped with zirconium (Zr) to hafnium oxide. As another example, hafnium zirconium oxide may be also a compound of hafnium (Hf), zirconium (Zr), and oxygen (O).

According to some example embodiments, the ferroelectric material film may further include a doped dopant. For example, the dopant may include at least one of aluminum (Al), titanium (Ti), niobium (Nb), lanthanum (La), yttrium (Y), magnesium (Mg), silicon (Si), calcium (Ca), cerium (Ce), dysprosium (Dy), erbium (Er), gadolinium (Gd), germanium (Ge), scandium (Sc), strontium (Sr), and tin (Sn). Depending on which ferroelectric material is included in the ferroelectric material film, a type of the dopant included in the ferroelectric material film may vary.

For example, when the ferroelectric material film includes hafnium oxide, the dopant included in the ferroelectric material film may include, for example, at least one of gadolinium (Gd), silicon (Si), zirconium (Zr), aluminum (Al), and yttrium (Y).

According to some example embodiments, when the dopant is aluminum (Al), the ferroelectric material film may include 3 to 8 atomic percent (at %) of aluminum. Here, a ratio of the dopant may be a ratio of aluminum to a sum of hafnium and aluminum.

According to some example embodiments, when the dopant is silicon (Si), the ferroelectric material film may include 2 to 10 at % of silicon. When the dopant is yttrium (Y), the ferroelectric material film may include 2 to 10 at % of yttrium. When the dopant is gadolinium (Gd), the ferroelectric material film may include 1 to 7 at % of gadolinium. When the dopant is zirconium (Zr), the ferroelectric material film may include 50 to 80 at % of zirconium.

According to some example embodiments, the paraelectric material film may have the paraelectric property. The paraelectric material film may include, for example, at least one of silicon oxide and metal oxide with high permittivity. For example, the metal oxide included in the paraelectric material film may include, but is not limited to, at least one of hafnium oxide, zirconium oxide, and aluminum oxide.

According to some example embodiments, the ferroelectric material film and the paraelectric material film may include an identical material. While the ferroelectric material film may have the ferroelectric property, the paraelectric material film may not have the ferroelectric property. For example, when the ferroelectric material film and the paraelectric material film include hafnium oxide, a crystal structure of hafnium oxide included in the ferroelectric material film is different from a crystal structure of hafnium oxide included in the paraelectric material film.

According to some example embodiments, the ferroelectric material film may have a thickness with the ferroelectric property. For example, the thickness of the ferroelectric material film may be, but is not limited to, 0.5 to 10 nanometers (nm). Since a threshold thickness representing the ferroelectric property may vary for each ferroelectric material, the thickness of the ferroelectric material film may vary depending on ferroelectric materials.

As an example, the gate insulating layer 130 may include one ferroelectric material film. As another example, the gate insulating layer 130 may include a plurality of ferroelectric material films spaced apart from each other. The gate insulating layer 130 may have a stacked layer structure in which a plurality of ferroelectric material films and a plurality of paraelectric material films are stacked alternately.

According to some example embodiments, the gate spacer 140 may be disposed at a side of the gate electrode 120 in the third direction D3. The gate spacer 140 may cover a sidewall of the gate electrode 120 in the third direction D3. The gate spacer 140 may be disposed between the substrate 100 and the plurality of first active patterns 200 and between the plurality of first active patterns 200 adjacent in the first direction D1.

According to some example embodiments, the gate spacer 140 may include an inner spacer 141 and an outer spacer 142. The inner spacer 141 and the outer spacer 142 may be disposed in the first direction D1. The inner spacer 141 and the outer spacer 142 may be called gate spacers.

According to some example embodiments, the inner spacer 141 may be disposed between the plurality of first active patterns 200 and the substrate 100 in the first direction D1. For example, the inner spacer 141 may be disposed between the plurality of first active patterns 200 adjacent to each other in the first direction D1. The inner spacer 141 may be disposed between the substrate 100 and a lowermost first active pattern 200 among the plurality of first active patterns 200. The inner spacer 141 may be disposed below an uppermost first active pattern 200 among the plurality of first active patterns 200.

According to some example embodiments, the outer spacer 142 may be disposed above the uppermost first active pattern 200 among the plurality of first active patterns 200. The outer spacer 142 may be disposed on a protective layer 110.

According to some example embodiments, the protective layer 110 may be disposed between the uppermost first active pattern 200 among the plurality of first active patterns 200 and the outer spacer 142 in the first direction D1. The protective layer 110 may include, for example, silicon nitride. The protective layer 110 may be disposed below the outer spacer 142 and at a side of the gate electrode 120 and the gate insulating layer 130. An outer side surface of the protective layer 110 may be disposed on the same plane as an outer side surface 142OSS of the outer spacer.

According to some example embodiments, a width W142 of the outer spacer in the third direction D3 may be greater than a width W141 of the inner spacer. The width W141 of the inner spacer in the third direction D3 may refer to a distance between outer side surfaces 141OSS of the inner spacer. The width W142 of the outer spacer in the third direction D3 may refer to a distance between the outer side surfaces 142OSS of the outer spacer.

The width W141 of the inner spacer in the third direction D3 is illustrated as smaller than the width W142 of the outer spacer in FIGS. 2 and 3, but example embodiments are not limited thereto. For example, the width W141 of the inner spacer in the third direction D3 may also be equal to the width W142 of the outer spacer or greater than the width W142 of the outer spacer.

According to some example embodiments, the gate spacer 140 may include, for example, at least one of silicon nitride (SiN), silicon oxynitride (SiON), silicon oxide (SiO₂), silicon oxycarbonitride (SiOCN), silicon boron nitride (SiBN), silicon oxyboron nitride (SiOBN), silicon oxycarbide (SiOC), and a combination thereof. The gate spacer 140 is illustrated as a single layer, which is merely for convenience of description, but is not limited thereto.

According to some example embodiments, the first source/drain pattern 150 may be connected to the plurality of first active patterns 200 in the third direction D3. A plurality of first source/drain patterns 150 may be disposed to be spaced apart in the third direction D3 with the plurality of first active patterns 200 in between. The first source/drain pattern 150 may be a source/drain of a transistor using the plurality of first active patterns 200 as a channel region. The first source/drain pattern 150 may be disposed between the gate electrodes 120 adjacent in the third direction D3. The first source/drain pattern 150 may be referred to as the source/drain pattern 150.

According to some example embodiments, the first source/drain pattern 150 may surround at least a portion of a first contact part 210. The first source/drain pattern 150 may cover an outer side surface of the first contact part 210. The first source/drain pattern 150 may cover at least a portion of an upper surface and a lower surface of the first contact part 210. An upper surface 150US of the first source/drain pattern and an upper surface 120US of the gate electrode may be disposed on the same plane.

According to some example embodiments, the first source/drain pattern 150 may include at least one of metal, metal alloy, conductive metal nitride, metal silicide, doped semiconductor material, conductive metal oxide, and conductive metal oxynitride. For example, the first source/drain pattern 150 may include, but is not limited to, at least one of titanium nitride (TiN), tantalum carbide (TaC), tantalum nitride (TaN), titanium silicon nitride (TiSiN), tantalum silicon nitride (TaSiN), tantalum titanium nitride (TaTiN), titanium aluminum nitride (TiAIN), tantalum aluminum nitride (TaAIN), tungsten nitride (WN), ruthenium (Ru), titanium aluminum (TiAl), titanium aluminum carbonitride (TiAIC-N), titanium aluminum carbide (TiAIC), titanium carbide (TiC), tantalum carbonitride (TaCN), tungsten (W), aluminum (Al), copper (Cu), cobalt (Co), titanium (Ti), tantalum (Ta), nickel (Ni), platinum (Pt), nickel platinum (Ni—Pt), niobium (Nb), niobium nitride (NbN), niobium carbide (NbC), molybdenum (Mo), molybdenum nitride (MoN), molybdenum carbide (MoC), tungsten carbide (WC), rhodium (Rh), palladium (Pd), iridium (Ir), osmium (Os), silver (Ag), gold (Au), zinc (Zn), vanadium (V), and a combination thereof. The conductive metal oxide and the conductive metal oxynitride may include, but are not limited to, an oxidized form of the materials described above.

According to some example embodiments, the plurality of first active patterns 200 may be disposed above the active region AR of the substrate 100. The plurality of first active patterns 200 may be disposed on the first interlayer insulating layer 101. For example, the plurality of first active patterns 200 may be an active pattern including a nanosheet or a nanowire. The plurality of first active patterns 200 may be disposed to be spaced apart from the substrate 100 in the first direction D1. The plurality of first active patterns 200 may be disposed to be spaced apart from each other in the first direction D1. The plurality of first active patterns 200 may extend between the first source/drain patterns 150 in the third direction D3. The plurality of first active patterns 200 may be referred to as the plurality of active patterns 200.

According to some example embodiments, in the third direction D3, the plurality of first active patterns 200 may be disposed between the first source/drain patterns 150. The plurality of first active patterns 200 may be connected to the first source/drain pattern 150.

According to some example embodiments, a width of the plurality of first active patterns 200 in the second direction D2 may be greater or smaller proportionally as being farther from the substrate 100 in the first direction D1. The width of the plurality of first active patterns 200 in the second direction D2 is illustrated as identical but is not limited thereto.

According to some example embodiments, the plurality of first active patterns 200 may include, for example, silicon or germanium, which are elemental semiconductor materials. In addition, the plurality of first active patterns 200 may include a compound semiconductor and may include, for example, a group IV-IV compound semiconductor or a group III-V compound semiconductor.

For example, the group IV-IV compound semiconductor may be a binary compound or a ternary compound including at least two or more of carbon (C), silicon (Si), germanium (Ge), and tin (Sn) or a compound doped with a group IV element thereto.

For example, the group III-V compound semiconductor may be one of a binary compound, a ternary compound, or a quaternary compound formed as at least one of aluminum (Al), gallium (Ga), and indium (In) which are group III elements and one of phosphorus (P), arsenic (As), and antimony (Sb) which are group V elements are combined.

The plurality of first active patterns 200 are illustrated as including groups of two in the first direction D1 in FIG. 2, but example embodiments are not limited thereto. For example, the plurality of first active patterns 200 may include groups of three or more in the first direction D1.

According to some example embodiments, the plurality of first active patterns 200 may protrude further toward the first source/drain pattern 150 than the gate structure GS in the third direction D3. A width W200 of the plurality of first active patterns in the third direction D3 may be greater than a width of the gate structure GS. The width W200 of the plurality of first active patterns in the third direction D3 may refer to a distance between the outer side surfaces of the first contact part 210 in contact with the first source/drain pattern 150. The width of the gate structure GS may refer to a greater one of the width W141 of the inner spacer and the width W142 of the outer spacer. The width W200 of the plurality of first active patterns in the third direction D3 may be greater than the width W141 of the inner spacer and the width W142 of the outer spacer.

According to some example embodiments, each of the plurality of first active patterns 200 may include a multilayer pattern disposed in the third direction D3. Each of the plurality of first active patterns 200 may include the first contact part 210 and the first connection part 220. Each multilayer pattern included in the plurality of first active patterns 200 may include the first contact part 210 and the first connection part 220. The first contact part 210 and the first connection part 220 may be disposed in the third direction D3. The first contact part 210 and the first connection part 220 may be connected to each other in the third direction D3. The first contact part 210 may be referred to as the contact part 210. The first connection part 220 may be referred to as the connection part 220.

According to some example embodiments, the first contact part 210 may be disposed further outside than the first connection part 220 in the third direction D3. The first contact part 210 may be in contact with the first source/drain pattern 150. At least a portion of the first contact part 210 may be inserted within the first source/drain pattern 150. At least a portion of the first contact part 210 may penetrate into the first source/drain pattern 150. At least a portion of the first contact part 210 may be surrounded by the first source/drain pattern 150.

According to some example embodiments, the first contact part 210 may protrude further toward the first source/drain pattern 150 than the gate structure GS in the third direction D3. The first contact part 210 may protrude further toward the first source/drain pattern 150 than the gate spacer 140 in the third direction D3. The first contact part 210 may protrude further toward the first source/drain pattern 150 than the outer side surfaces 141OSS and 142OSS of the gate spacer in the third direction D3.

According to some example embodiments, at least a portion of the first contact part 210 may overlap with the gate spacer 140 in the first direction D1. At least a portion of the first contact part 210 may overlap with the inner spacer 141 in the first direction D1. At least a portion of the first contact part 210 may overlap with the outer spacer 142 in the first direction D1.

Components or layers described with reference to “overlap” in a particular direction may be at least partially obstructed by one another when viewed along a line extending in the particular direction or in a plane perpendicular to the particular direction. The term “surrounding” or “covering” or “filling” as may be used herein may not require completely surrounding or covering or filling the described elements or layers, but may, for example, refer to partially surrounding or covering or filling the described elements or layers, for example, with voids, spaces, or other discontinuities throughout. The term “exposed,” may be used to describe relationships between elements and/or certain intermediate processes in fabricating a completed semiconductor device, but may not necessarily require exposure of the particular region, layer, structure or other element in the context of the completed device.

According to some example embodiments, the first connection part 220 may be disposed between the first contact parts 210 along the third direction D3. The first connection part 220 may connect the first contact parts 210 spaced apart along the third direction D3. The first connection part 220 may overlap with the gate electrode 120 in the first direction D1. The first connection part 220 may extend from the first contact part 210 away from the first source/drain pattern 150 in the third direction D3.

According to some example embodiments, the width W220 of the first connection part in the third direction D3 may be smaller than a width of the gate spacer 140. The width W220 of the first connection part in the third direction D3 may be smaller than the width W141 of the inner spacer. The width W220 of the first connection part in the third direction D3 may be smaller than the width W142 of the outer spacer.

According to some example embodiments, the first contact part 210 may include a transition metal. The first contact part 210 may include at least one material among molybdenum (Mo), tungsten (W), vanadium (V), niobium (Nb), tantalum (Ta), and titanium (Ti). However, example embodiments are not limited thereto. The first contact part 210 including the transition metal may alleviate resistance generated between the first connection part 220 and the first source/drain pattern 150.

According to some example embodiments, the first connection part 220 may include a two-dimensional material. The first connection part 220 may include MoS2, MoSe2, MoTe2, WS2, WSe2, MoTe2, or PtSe2. The first connection part 220 may include a transition metal dichalcogenide (TMD).

According to some example embodiments, the first contact part 210 and the first connection part 220 may include an identical transition metal material to each other. Here an identical material may include the same material or element in a same or different amount or in a same or different compound. Further, an item comprising a specific element or compound encompasses any item including the specific element or compound singly or in combination with other elements and compounds. Each of the first contact part 210 and the first connection part 220 may include at least one material among molybdenum (Mo), tungsten (W), vanadium (V), niobium (Nb), tantalum (Ta), and titanium (Ti).

According to some example embodiments, the first source/drain contact 170 may be disposed above the upper surface of the substrate 100. The first source/drain contact 170 may be disposed on an upper surface of the first source/drain pattern 150. The first source/drain contact 170 may be connected to the first source/drain pattern 150. The first source/drain contact 170 may penetrate a second interlayer insulating layer 191 and a first etch stop layer 161 and be connected to the first source/drain pattern 150.

According to some example embodiments, the first source/drain contact 170 may include a first source/drain contact barrier layer 170a and a first source/drain contact filling layer 170b placed on the first source/drain contact barrier layer 170a. The first source/drain contact barrier layer 170a may extend along a sidewall and a bottom surface of the first source/drain contact filling layer 170b.

According to some example embodiments, with respect to the upper surface of the substrate 100, an upper surface of the first source/drain contact barrier layer 170a is illustrated as being positioned at a substantially identical height to an upper surface of the first source/drain contact filling layer 170b but is not limited thereto. Unlike what is illustrated, with respect to the upper surface of the substrate 100, the upper surface of the first source/drain contact barrier layer 170a may be lower than the upper surface of the first source/drain contact filling layer 170b.

According to some example embodiments, the first source/drain contact barrier layer 170a may include, for example, at least one of tantalum (Ta), tantalum nitride (TaN), titanium (Ti), titanium nitride (TiN), titanium silicon nitride (TiSiN), ruthenium (Ru), cobalt (Co), nickel (Ni), nickel boron (NiB), tungsten (W), tungsten nitride (WN), tungsten carbonitride (WCN), zirconium (Zr), zirconium nitride (ZrN), vanadium (V), vanadium nitride (VN), niobium (Nb), niobium nitride (NbN), platinum (Pt), iridium (Ir), rhodium (Rh), and a 2D material. In the semiconductor device according to some example embodiments, the 2D material may be a metallic material and/or a semiconductor material. The 2D material may include a 2D allotrope or a 2D compound and may include, for example, at least one of graphene, molybdenum disulfide (MoS2), molybdenum diselenide (MoSe2), tungsten diselenide (WSe2), and tungsten disulfide (WS2) but is not limited thereto. In other words, since the 2D materials described above are enumerated merely as examples, the 2D material that may be included in the semiconductor device of the present disclosure is not limited to the aforementioned materials.

According to some example embodiments, the first source/drain contact filling layer 170b may include, for example, at least one of aluminum (Al), tungsten (W), cobalt (Co), ruthenium (Ru), silver (Ag), gold (Au), manganese (Mn), and molybdenum (Mo).

According to some example embodiments, the first source/drain contact 170 is illustrated as including a plurality of conductive layers but is not limited thereto. Unlike what is illustrated, the first source/drain contact 170 may also be a single layer.

According to some example embodiments, the first gate contact 180 may be disposed on the gate electrode 120. The first gate contact 180 may penetrate the second interlayer insulating layer 191 and the first etch stop layer 161 and be connected to the gate electrode 120. The first gate contact 180 may be connected to the first wiring via 301. An upper surface of the first gate contact 180 may be placed on the same plane as an upper surface of the first source/drain contact 170.

According to some example embodiments, the first gate contact 180 may include a first gate contact barrier layer 180a and a first gate contact filling layer 180b placed on the first gate contact barrier layer 180a. A description of materials included in the first gate contact barrier layer 180a and the first gate contact filling layer 180b is identical to the description of materials included in the first source/drain contact barrier layer 170a and the first source/drain contact filling layer 170b and thus omitted.

According to some example embodiments, the first wiring via 301 may be disposed on the first source/drain contact 170 and the first gate contact 180. The first wiring via 301 may penetrate a third interlayer insulating layer 192 and a second etch stop layer 162 and be connected to the first source/drain contact 170 and the first gate contact 180. The first wiring via 301 may be connected to the first wiring layer 311. The first wiring via 301 may include a first via barrier layer 301a and a first via filling layer 301b. The first via barrier layer 301a may extend along a side surface and a bottom surface of the first via filling layer 301b.

According to some example embodiments, the first via barrier layer 301a may include at least one of tantalum (Ta), tantalum nitride (TaN), titanium (Ti), titanium nitride (TiN), titanium silicon nitride (TiSiN), nickel (Ni), nickel boron (NiB), tungsten nitride (WN), tungsten carbonitride (WCN), zirconium (Zr), zirconium nitride (ZrN), vanadium (V), vanadium nitride (VN), niobium (Nb), niobium nitride (NbN), platinum (Pt), iridium (Ir), rhodium (Rh), and a 2D material. For example, the first via filling layer 301b may include at least one of aluminum (Al), tungsten (W), cobalt (Co), ruthenium (Ru), copper (Cu), silver (Ag), gold (Au), manganese (Mn), and molybdenum (Mo).

In some example embodiments, the first wiring layer 311 may penetrate a fourth interlayer insulating layer 193 and a third etch stop layer 163 and be connected to the first wiring via 301. The first wiring layer 311 may be connected to the first source/drain contact 170 and the first gate contact 180 through the first wiring via 301. The first wiring layer 311 may include a first wiring barrier layer 311a and a first wiring filling layer 311b. A description of the first wiring barrier layer 311a and the first wiring filling layer 311b is substantially identical to the description of the first via barrier layer 301a and the first via filling layer 301b and thus omitted.

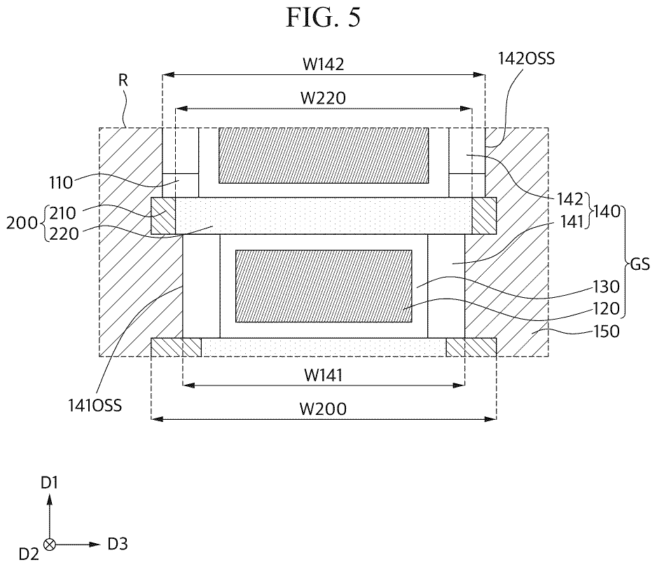

FIG. 5 is an example enlarged view showing part R of FIG. 2 to illustrate a semiconductor device according to other example embodiments. To illustrate the semiconductor device according to other example embodiments, a difference from the description with reference to FIGS. 1 to 4 is mainly described.

Referring to FIG. 5, the width W220 of the first connection part in the third direction D3 may be greater than the width W141 of the inner spacer. The first connection part 220 may protrude further toward the first source/drain pattern 150 than the inner spacer 141 in the third direction D3. The inner spacer 141 may overlap with the first connection part 220 in the first direction D1.

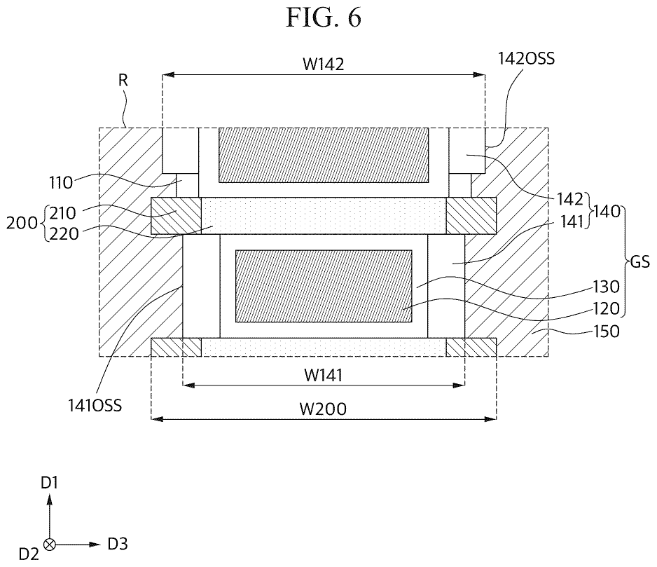

FIG. 6 is an example enlarged view showing part R of FIG. 2 to illustrate a semiconductor device according to some other example embodiments. To illustrate the semiconductor device according to some other example embodiments, a difference from the description with reference to FIGS. 1 to 4 is mainly described.

Referring to FIG. 6, the outer side surface of the protective layer 110 may not be disposed on the same plane as the outer side surface 142OSS of the outer spacer. The outer spacer 142 may protrude further toward the first source/drain pattern 150 than the protective layer 110 in the third direction D3. A width between the outer side surfaces of the protective layer 110 in the third direction D3 may be smaller than the width W142 of the outer spacer. At least a portion of the first source/drain pattern 150 may be inserted in a space formed by the outer spacer 142 and the protective layer 110.

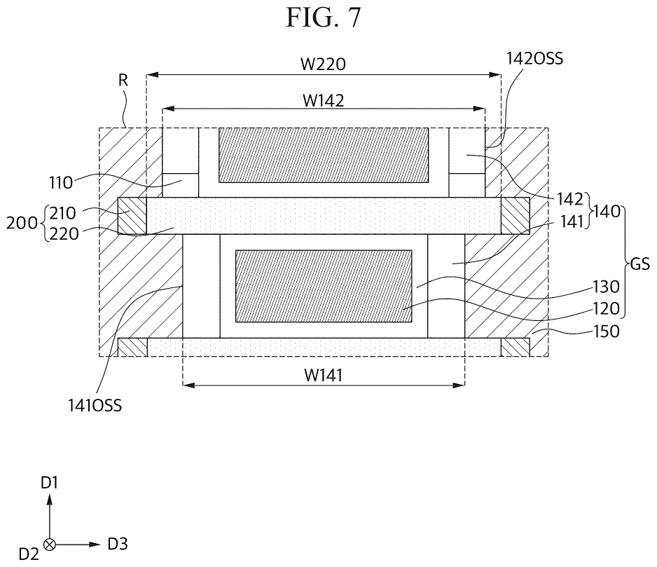

FIG. 7 is an example enlarged view showing part R of FIG. 2 to illustrate a semiconductor device according to still other example embodiments. To illustrate the semiconductor device according to still other example embodiments, a difference from the description with reference to FIGS. 1 to 4 is mainly described.

Referring to FIG. 7, the width W220 of the first connection part in the third direction D3 may be greater than the width of the gate structure GS. The width W220 of the first connection part in the third direction D3 may be greater than the width W141 of the inner spacer. The width W220 of the first connection part in the third direction D3 may be greater than the width W142 of the outer spacer.

According to some example embodiments, the first connection part 220 may protrude further toward the first source/drain pattern 150 than the gate spacer 140 in the third direction D3. The first connection part 220 may protrude further toward the first source/drain pattern 150 than the outer side surface 142OSS of the outer spacer in the third direction D3. The first connection part 220 may protrude further toward the first source/drain pattern 150 than the outer side surface 141OSS of the inner spacer in the third direction D3. At least a portion of the first connection part 220 may be surrounded by the first source/drain pattern 150. At least a portion of an upper surface and a lower surface of the first connection part 220 disposed in the first direction D1 may be covered by the first source/drain pattern 150.

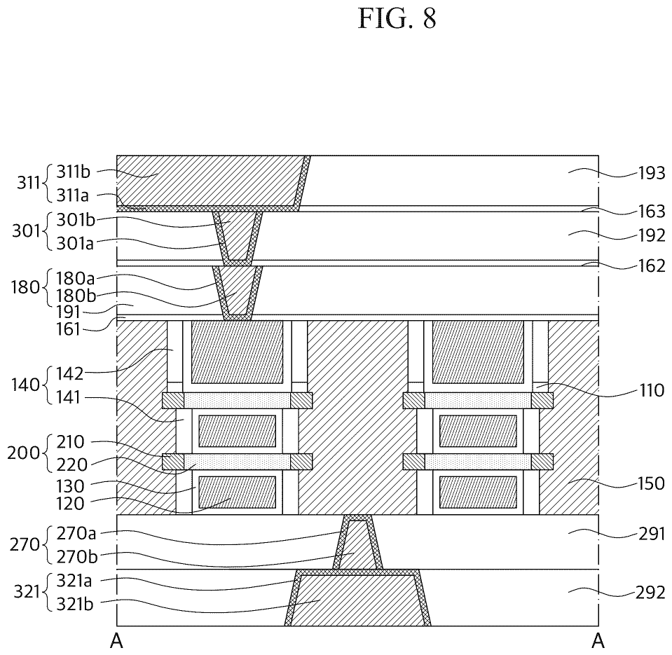

FIG. 8 is an example diagram showing a cross-section taken along line A-A of FIG. 1 to illustrate a semiconductor device according to yet other example embodiments. To illustrate the semiconductor device according to yet other example embodiments, a difference from the description with reference to FIGS. 1 to 4 is mainly described.

Referring to FIG. 8, the semiconductor device according to yet other example embodiments may include a second source/drain contact 270 and a second wiring layer 321.

According to some example embodiments, the second source/drain contact 270 may be disposed on a lower surface of the first source/drain pattern 150. The second source/drain contact 270 may be connected to the first source/drain pattern 150. The second source/drain contact 270 may penetrate a fifth interlayer insulating layer 291 and be connected to the first source/drain pattern 150. The second source/drain contact 270 may include a second source/drain contact barrier layer 270a and a second source/drain contact filling layer 270b placed on the second source/drain contact barrier layer 270a. A description of the second source/drain contact barrier layer 270a and the second source/drain contact filling layer 270b is substantially identical to the description of the first source/drain contact barrier layer 170a and the first source/drain contact filling layer 170b and thus omitted.

According to some example embodiments, the second wiring layer 321 may be disposed below the gate electrode 120 and the first source/drain pattern 150. The second wiring layer 321 may be disposed below the second source/drain contact 270. The second wiring layer 321 may penetrate a sixth interlayer insulating layer 292 and be connected to the second source/drain contact 270. The second wiring layer 321 may include a second wiring barrier layer 321a and a second wiring filling layer 321b. A description of the second wiring barrier layer 321a and the second wiring filling layer 321b is substantially identical to the description of the first wiring barrier layer 311a and the first wiring filling layer 311b and thus omitted.

The second source/drain contact 270 is illustrated as being directly connected to the second wiring layer 321 in FIG. 8, but example embodiments are not limited thereto. For example, similarly to the first source/drain contact 170 being connected to the first wiring layer 311 through the first wiring via 301, a second wiring via may also be disposed between the second source/drain contact 270 and the second wiring layer 321.

FIG. 8 illustrates that only the second source/drain contact 270 is disposed below the gate electrode 120 and the first source/drain pattern 150, but example embodiments are not limited thereto. For example, a second gate contact placed below the gate electrode 120 and connected to the gate electrode 120 may be disposed. The second gate contact may penetrate the fifth interlayer insulating layer 291 and be connected to the gate electrode 120 and the second wiring layer 321.

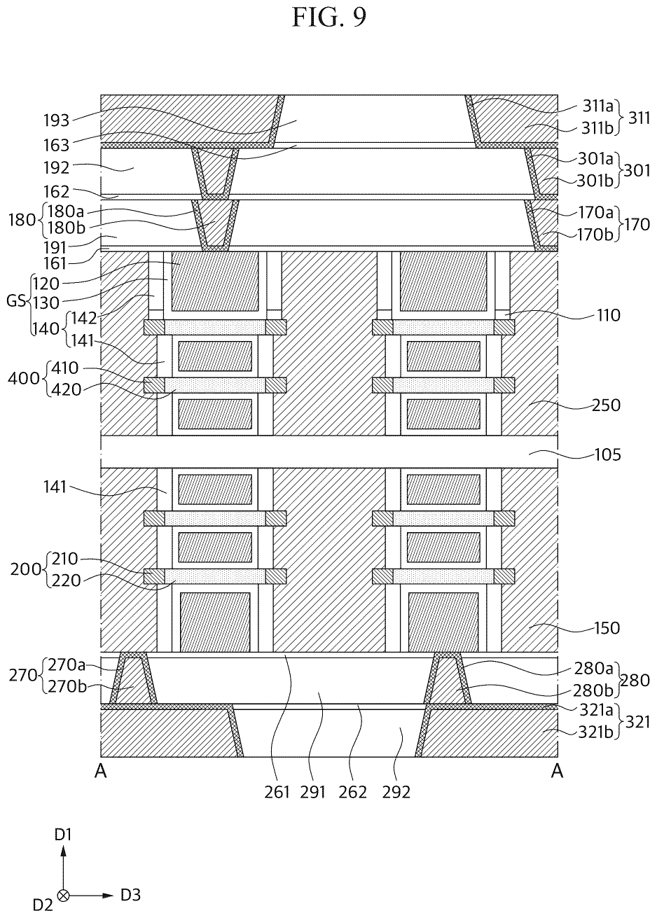

FIG. 9 is an example diagram showing a cross-section taken along line A-A of FIG. 1 to illustrate a semiconductor device according to yet some other example embodiments.

Referring to FIG. 9, the semiconductor device according to yet some other example embodiments may include the plurality of first active patterns 200, a plurality of second active patterns 400, the first source/drain pattern 150, and a second source/drain pattern 250.

According to some example embodiments, the plurality of first active patterns 200 and the plurality of second active patterns 400 may be disposed in the first direction D1. The plurality of first active patterns 200 may be disposed below a separation insulating layer 105. The plurality of second active patterns 400 may be disposed above the separation insulating layer 105.

According to some example embodiments, the plurality of first active patterns 200 may be connected to the first source/drain pattern 150. At least a portion of the first contact part 210 of the plurality of first active patterns 200 may be surrounded by the first source/drain pattern 150. The second contact part 410 of the plurality of first active patterns 200 may be inserted within the second source/drain pattern 250.

According to some example embodiments, the plurality of second active patterns 400 may include a second contact part 410 and a second connection part 420. A description of the second contact part 410 and the second connection part 420 is substantially identical to the description of the first contact part 210 and the first connection part 220 and thus omitted.

According to some example embodiments, the plurality of second active patterns 400 may be connected to the second source/drain pattern 250. At least a portion of the second contact part 410 of the plurality of second active patterns 400 may be surrounded by the second source/drain pattern 250. The second contact part 410 of the plurality of second active patterns 400 may be inserted within the first source/drain pattern 150.

According to some example embodiments, the gate electrode 120 may surround the plurality of first active patterns 200 and the plurality of second active patterns 400. The gate electrode 120 may overlap with the first connection part 220 of the plurality of first active patterns 200 and the second connection part 420 of the plurality of second active patterns 400 in the first direction D1.

According to some example embodiments, the first source/drain pattern 150 and the second source/drain pattern 250 may be disposed in the first direction D1. The first source/drain pattern 150 and the second source/drain pattern 250 may be spaced apart with the separation insulating layer 105 in between. The first source/drain pattern 150 may be disposed below the separation insulating layer 105. The second source/drain pattern 250 may be disposed on and above the separation insulating layer 105.

According to some example embodiments, the first source/drain pattern 150 and the second source/drain pattern 250 may have different conductive types. For example, the first source/drain pattern 150 may have a p-type, and the second source/drain pattern 250 may have an n-type. The first source/drain pattern 150 may include a p-type dopant. The p-type dopant may include, but is not limited to, at least one of boron (B) and gallium (Ga). The second source/drain pattern 250 may include an n-type dopant. The n-type dopant may include, but is not limited to, at least one of phosphorus (P), arsenic (As), antimony (Sb), and bismuth (Bi). For other example embodiments, the first source/drain pattern 150 may have the n-type, and the second source/drain pattern 250 may have the p-type.

According to some example embodiments, the first source/drain pattern 150 may be connected to the plurality of first active patterns 200. The first source/drain pattern 150 may be disposed between the plurality of first active patterns 200 in the third direction D3. The first source/drain pattern 150 may be disposed between the gate electrodes 120 adjacent in the third direction D3.

According to some example embodiments, the first source/drain pattern 150 may be a source/drain of a p-type metal-oxide-semiconductor (PMOS) transistor. The first source/drain pattern 150 may be a source/drain of a transistor using the plurality of first active patterns 200 as a channel region.

According to some example embodiments, the second source/drain pattern 250 may be connected to the plurality of second active patterns 400. The second source/drain pattern 250 may be disposed between the plurality of second active patterns 400 in the third direction D3. The second source/drain pattern 250 may be disposed between the gate electrodes 120 adjacent in the third direction D3.

According to some example embodiments, the second source/drain pattern 250 may be a source/drain of an n-type metal-oxide-semiconductor (NMOS) transistor. The second source/drain pattern 250 may be a source/drain of a transistor using the plurality of second active patterns 400 as a channel region.

According to some example embodiments, the second source/drain contact 270 may be disposed below the first source/drain pattern 150. The second source/drain contact 270 may penetrate the fifth interlayer insulating layer 291 and a fourth etch stop layer 261 and be connected to the first source/drain pattern 150. A description of the second source/drain contact 270 is substantially identical to the description of the second source/drain contact 270 with reference to FIG. 8 and thus omitted.

According to some example embodiments, a second gate contact 280 may be disposed below the gate electrode 120. The second gate contact 280 may penetrate the fifth interlayer insulating layer 291 and the fourth etch stop layer 261 and be connected to the gate electrode 120. A description of the second gate contact 280 is substantially identical to the description of the second source/drain contact 270 with reference to FIG. 8 and thus omitted.

According to some example embodiments, the second wiring layer 321 may be disposed below the second source/drain contact 270 and the second gate contact 280. The second wiring layer 321 may penetrate the sixth interlayer insulating layer 292 and a fifth etch stop layer 262 and be connected to the second source/drain contact 270 and the second gate contact 280. A description of the second wiring layer 321 is substantially identical to the description of the second wiring layer 321 with reference to FIG. 8 and thus omitted.

According to some example embodiments, the first source/drain contact 170 may be disposed on the second source/drain pattern 250. The first source/drain contact 170 may be disposed on an upper surface of the second source/drain pattern 250.

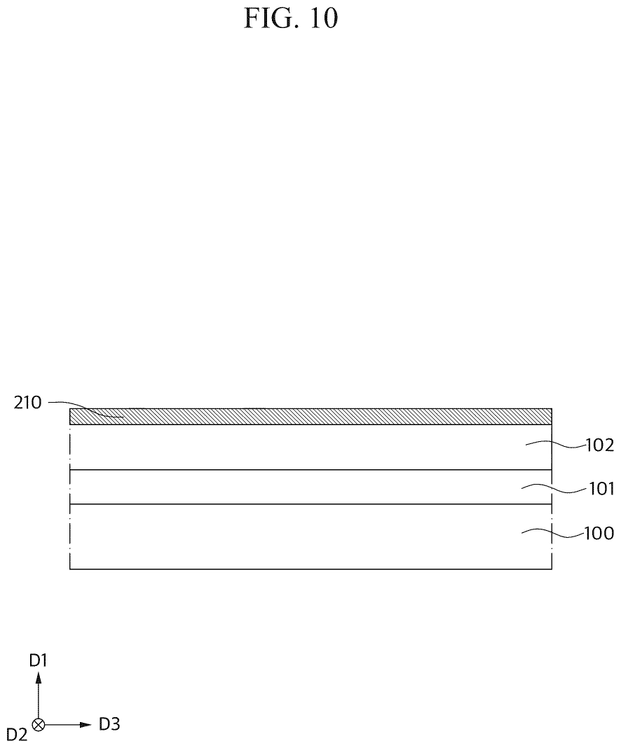

FIGS. 10 to 24 are example diagrams showing intermediate operations for illustrating a method of manufacturing a semiconductor device according to some example embodiments illustrated in FIG. 2.

Referring to FIG. 10, the first interlayer insulating layer 101, a first sacrificial layer 102, and the first contact part 210 may be formed above the substrate 100. The first contact part 210 may extend along an upper surface of the first sacrificial layer 102. The first contact part 210 may cover the first sacrificial layer 102. The first contact part 210 may include a transition metal. The first contact part 210 may include at least one material among molybdenum (Mo), tungsten (W), vanadium (V), niobium (Nb), tantalum (Ta), and titanium (Ti). The first sacrificial layer 102 may include a silicon oxide layer.

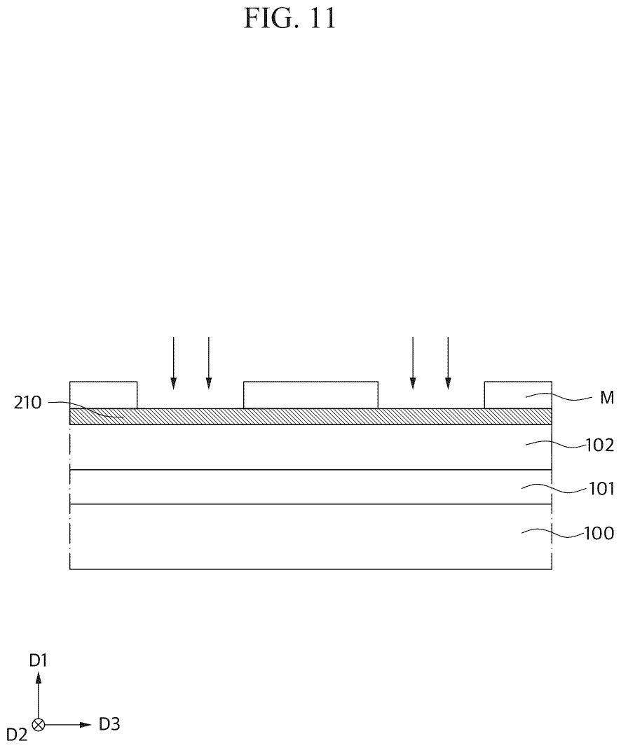

Referring to FIG. 11, a mask M may be formed on the first contact part 210. A portion of the first contact part 210 may be exposed through the mask M. A chemical treatment may be performed for the portion of the first contact part 210 exposed through the mask M. For example, a sulfur treatment may be performed using a process gas or a precursor including H2S for the portion of the first contact part 210 exposed through the mask M.

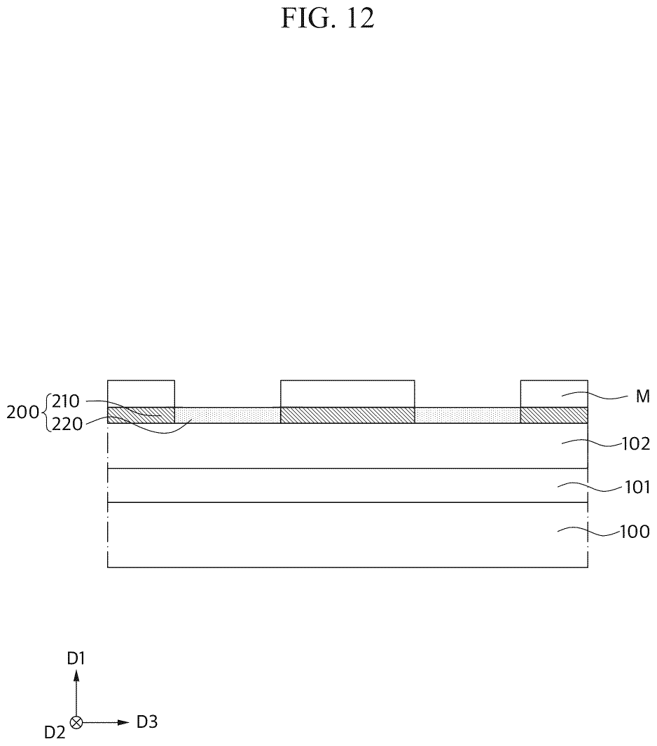

Referring to FIG. 12, the first connection part 220 may be formed in the portion exposed through the mask M. The first connection part 220 may be formed by chemically treating the first contact part 210. The first connection part 220 may include an identical transition metal element to the first contact part 210. The first connection part 220 may include a 2D material formed through the chemical treatment.

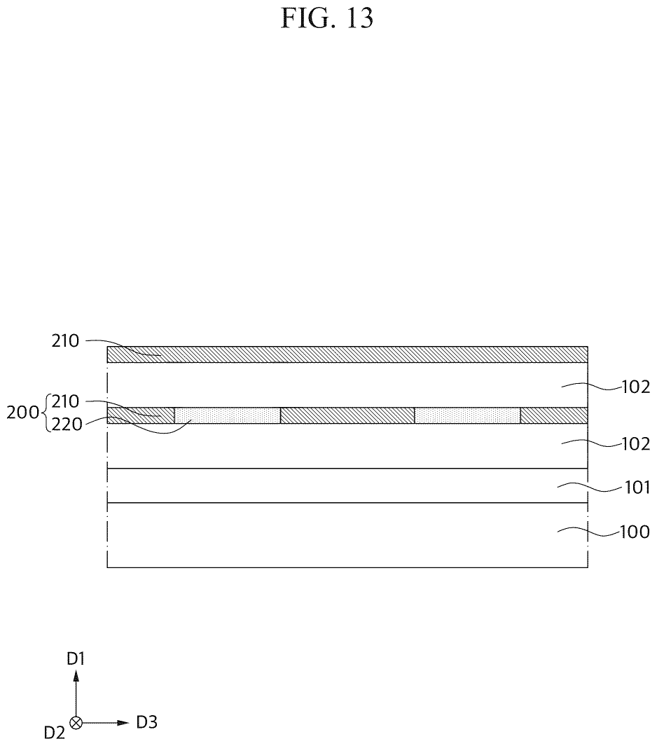

Referring to FIG. 13, the first sacrificial layer 102 and the first contact part 210 may be formed above one first active pattern 200.

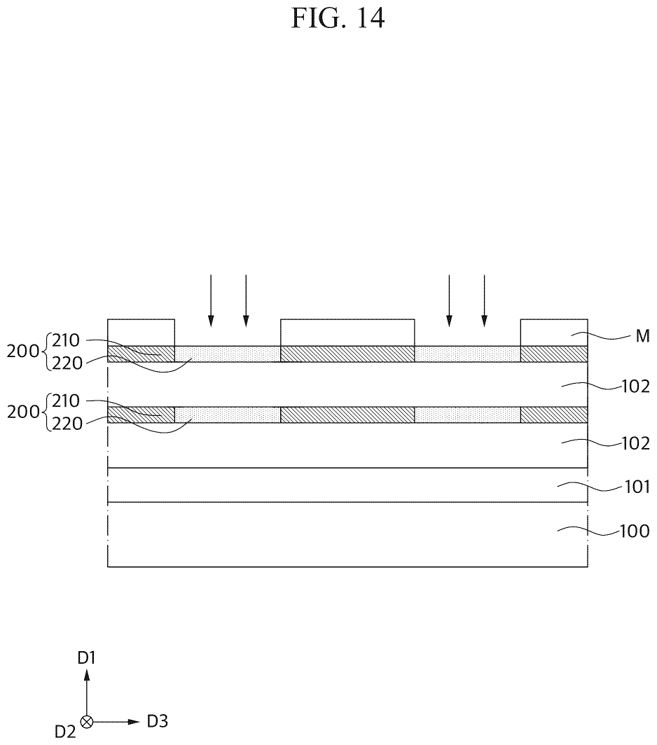

Referring to FIG. 14, similarly to the description with reference to FIGS. 11 and 12, the mask M for exposing the portion of the first contact part 210 may be formed on the first contact part 210, and as the portion of the first contact part 210 exposed through the mask M is chemically treated, the first connection part 220 may be formed. The plurality of first active patterns 200 including the first contact part 210 and the first connection part 220 may be formed in sequence along the first direction D1.

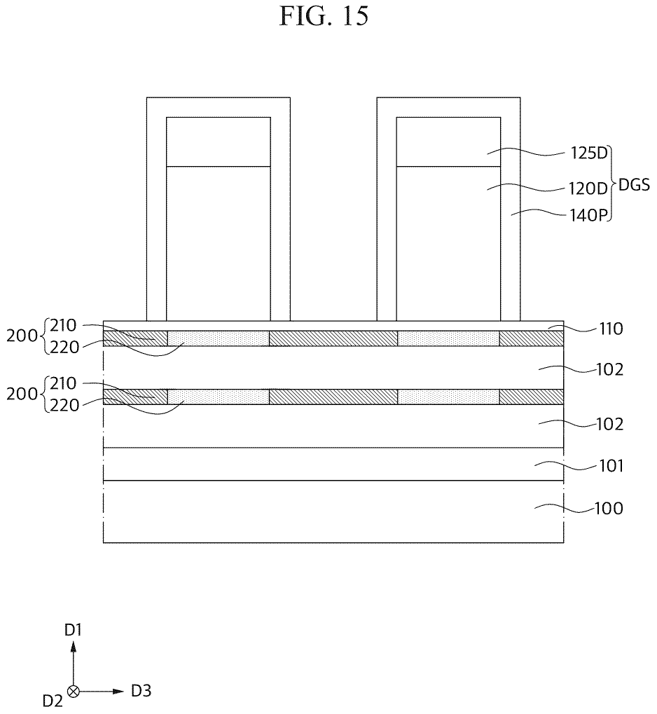

Referring to FIG. 15, the protective layer 110 and a dummy gate structure DGS may be formed above the plurality of first active patterns 200. The protective layer 110 may cover the uppermost first active pattern 200.

According to some example embodiments, the dummy gate structure DGS may be formed on the protective layer 110. The dummy gate structure DGS may include a dummy gate electrode 120D, a pre-gate spacer 140P, and a dummy gate capping layer 125D. The dummy gate capping layer 125D may be disposed on the dummy gate electrode 120D. The dummy gate electrode 120D and the dummy gate capping layer 125D may be disposed in the first direction D1.

According to some example embodiments, each of the dummy gate electrode 120D and the dummy gate capping layer 125D may include at least one of silicon nitride (SiN), silicon oxynitride (SiON), silicon oxide (SiO₂), silicon oxycarbonitride (SiOCN), silicon boron nitride (SiBN), silicon oxyboron nitride (SiOBN), silicon oxycarbide (SiOC), and a combination thereof. For example, the dummy gate electrode 120D may include silicon oxide and the dummy gate capping layer 125D may include silicon nitride.

According to some example embodiments, the pre-gate spacer 140P may be disposed along a surface of the dummy gate electrode 120D and a surface of the dummy gate capping layer 125D. The pre-gate spacer 140P may cover the surface of the dummy gate electrode 120D and the surface of the dummy gate capping layer 125D. The pre-gate spacer 140P may include at least one of silicon nitride (SiN), silicon oxynitride (SiON), silicon oxide (SiO2), silicon oxycarbonitride (SiOCN), silicon boron nitride (SiBN), silicon oxyboron nitride (SiOBN), silicon oxycarbide (SiOC), and a combination thereof.

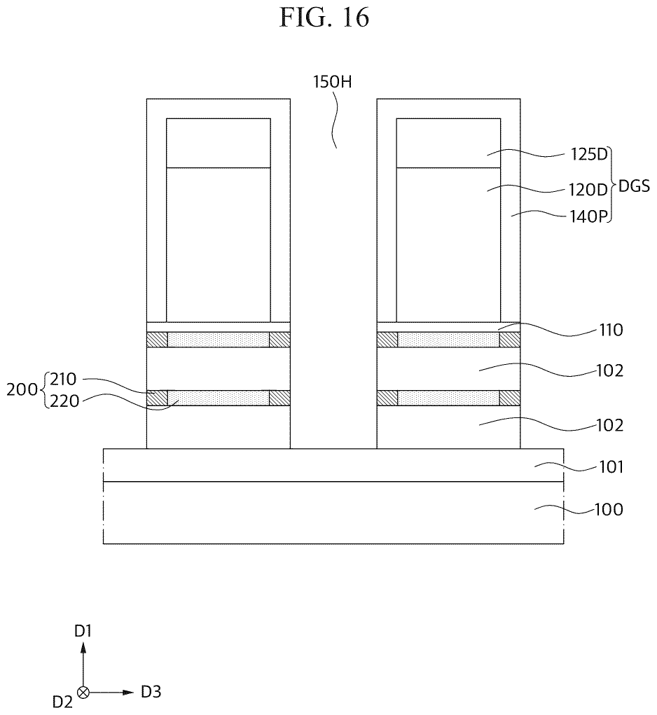

Referring to FIG. 16, a first source/drain pattern hole 150H may be formed using the dummy gate structure DGS. The plurality of first active patterns 200 and the first sacrificial layer 102 may be patterned using the dummy gate structure DGS as a mask. As the plurality of first active patterns 200 and the first sacrificial layer 102 are cut in the third direction D3, the first source/drain pattern hole 150H may be formed.

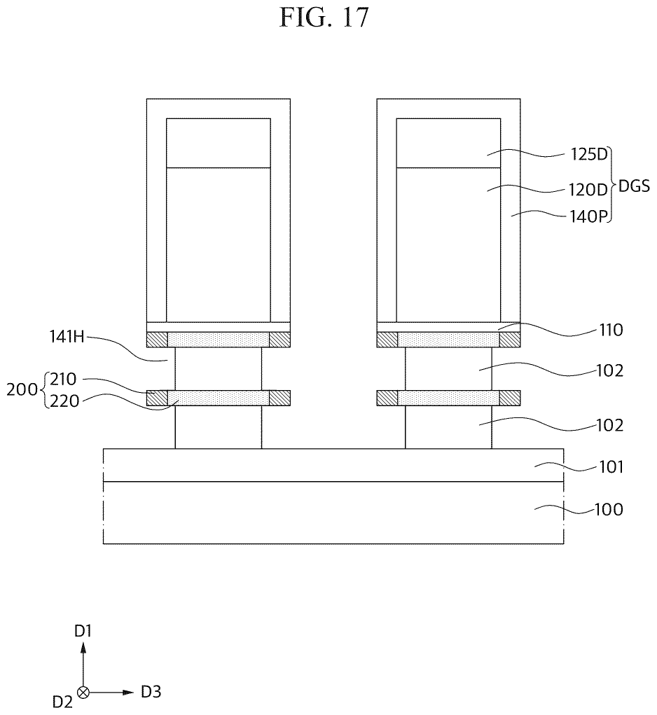

Referring to FIG. 17, a portion of the first sacrificial layer 102 may be removed and an inner spacer hole 141H may be formed. The portion of the first sacrificial layer 102 exposed within the first source/drain pattern hole 150H of FIG. 16 may be removed. A width of the first sacrificial layer 102 in the third direction D3 may be smaller than a width of the plurality of first active patterns 200. The inner spacer hole 141H may be defined by the plurality of first active patterns 200 and the first sacrificial layer 102.

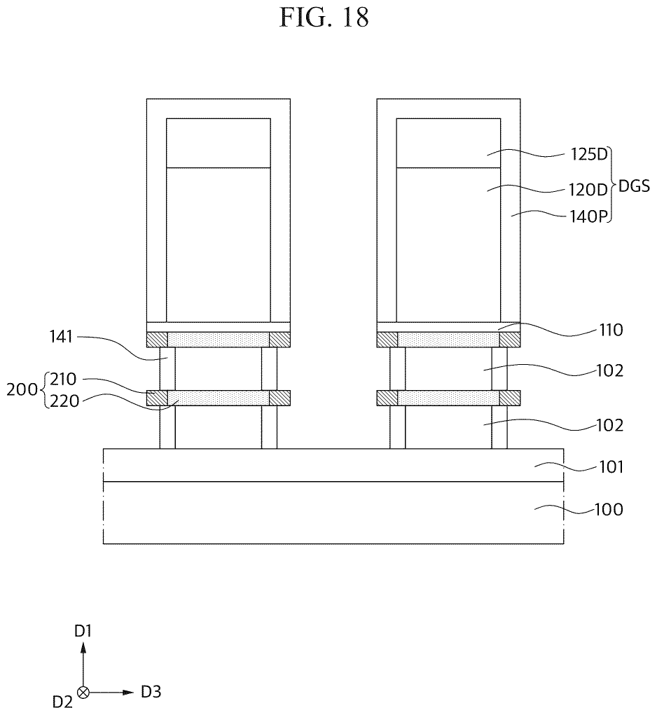

Referring to FIG. 18, the inner spacer 141 may be formed on a side of the first sacrificial layer 102. The inner spacer 141 may be disposed between the plurality of first active patterns 200 in the first direction D1.

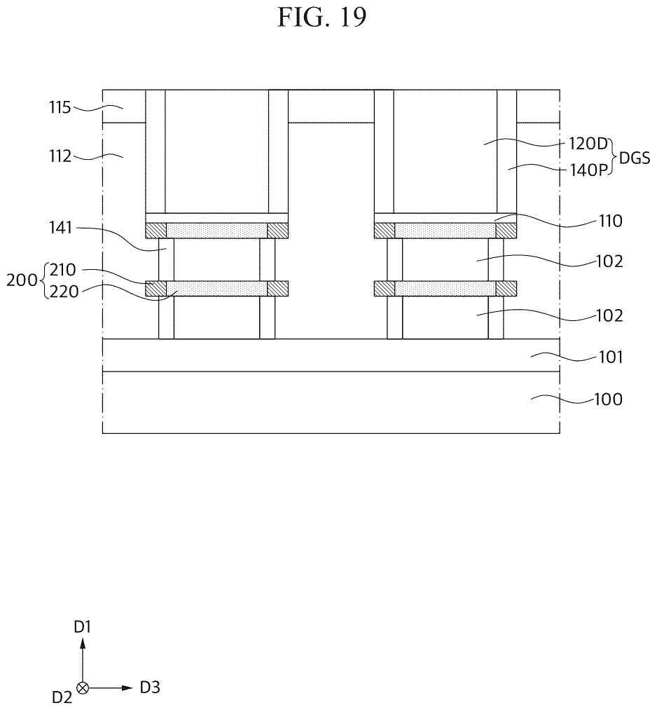

Referring to FIG. 19, a second sacrificial layer 112 covering the plurality of first active patterns 200, the inner spacer 141, and the dummy gate structure DGS and a sacrificial capping layer 115 may be formed. The second sacrificial layer 112 may include, for example, silicon oxide. The sacrificial capping layer 115 may include, for example, silicon nitride.

According to some example embodiments, the second sacrificial layer 112 may fill the first source/drain pattern hole 150H of FIG. 16. The sacrificial capping layer 115 may be formed on the second sacrificial layer 112. The sacrificial capping layer 115 may cover the second sacrificial layer 112. In the process of forming the second sacrificial layer 112 and the sacrificial capping layer 115, the dummy gate capping layer 125D of FIG. 18 may be removed through a polishing process.

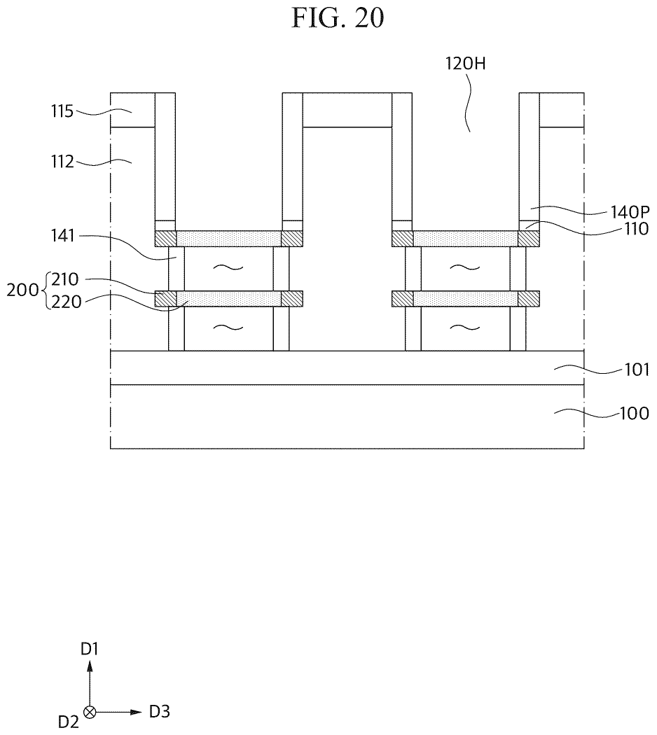

Referring to FIG. 20, the dummy gate electrode 120D of FIG. 19 may be removed. While the dummy gate electrode 120D of FIG. 19 is removed, a portion of the protective layer 110 may be removed together. While the dummy gate electrode 120D of FIG. 19 and the portion of the protective layer 110 are removed, a surface of the plurality of first active patterns 200 may be exposed. While the dummy gate electrode 120D of FIG. 19 is removed, an empty space may be formed between the plurality of first active patterns 200 spaced apart in the first direction D1.

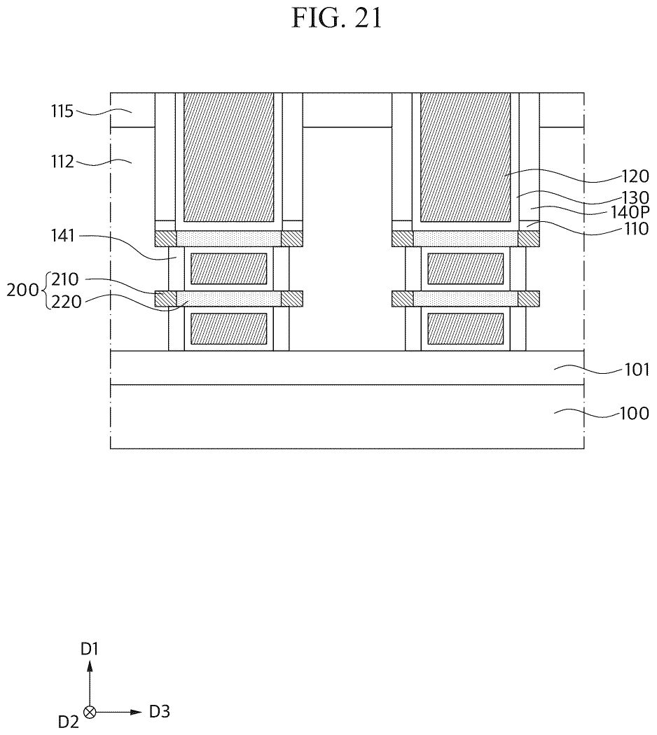

Referring to FIG. 21, the gate electrode 120 and the gate insulating layer 130 may be formed. The gate electrode 120 and the gate insulating layer 130 may be formed to surround the surface of the plurality of first active patterns 200.

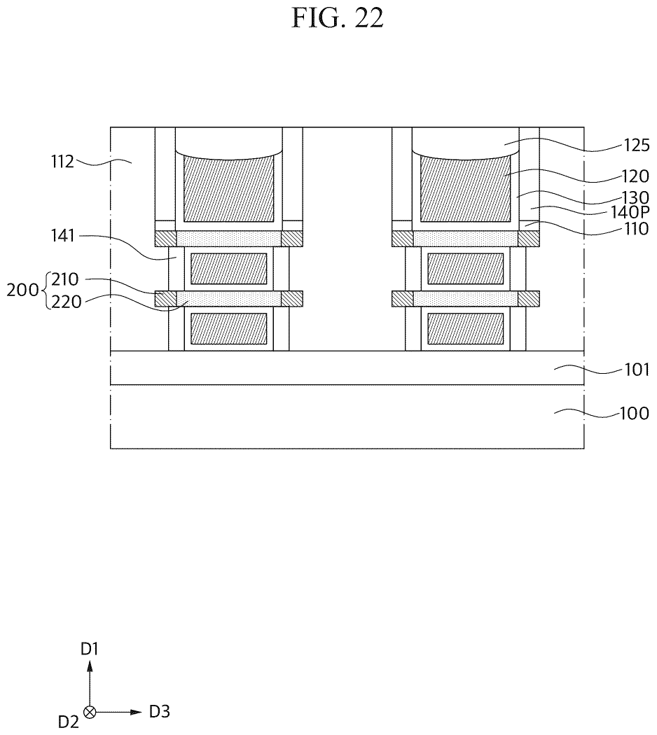

Referring to FIG. 22, a gate capping layer 125 may be formed on the gate electrode 120 and the gate insulating layer 130. The gate capping layer 125 may be formed as a portion of the gate electrode 120 is removed. In the process of forming the gate capping layer 125, the sacrificial capping layer 115 of FIG. 21 may be removed through a polishing process.

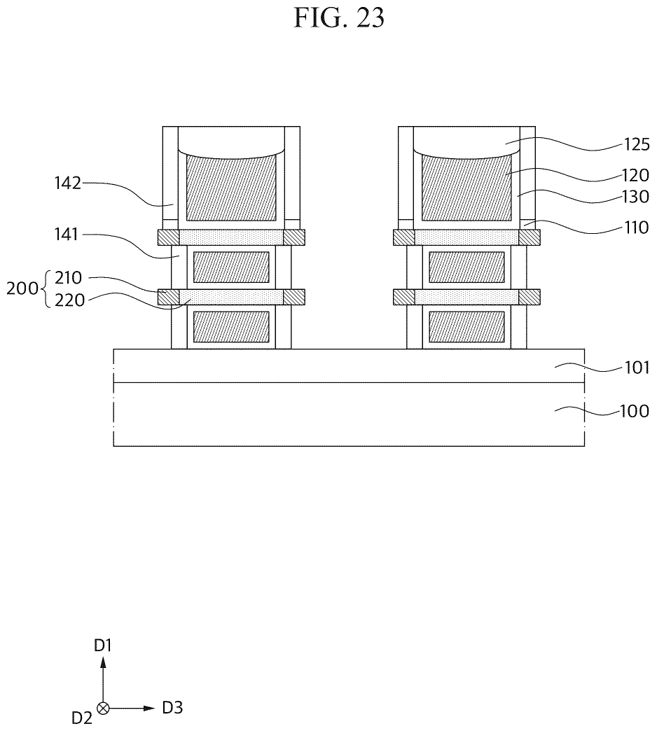

Referring to FIG. 23, the second sacrificial layer 112 of FIG. 22 may be removed. While the second sacrificial layer 112 of FIG. 22 is removed, a portion of the pre-gate spacer 140P of FIG. 21 may be removed together and the outer spacer 142 may be formed. As the second sacrificial layer 112 of FIG. 22 is removed, the first contact part 210 of the plurality of first active patterns 200 may be exposed. The first contact part 210 may protrude further outside than the gate spacer 140.

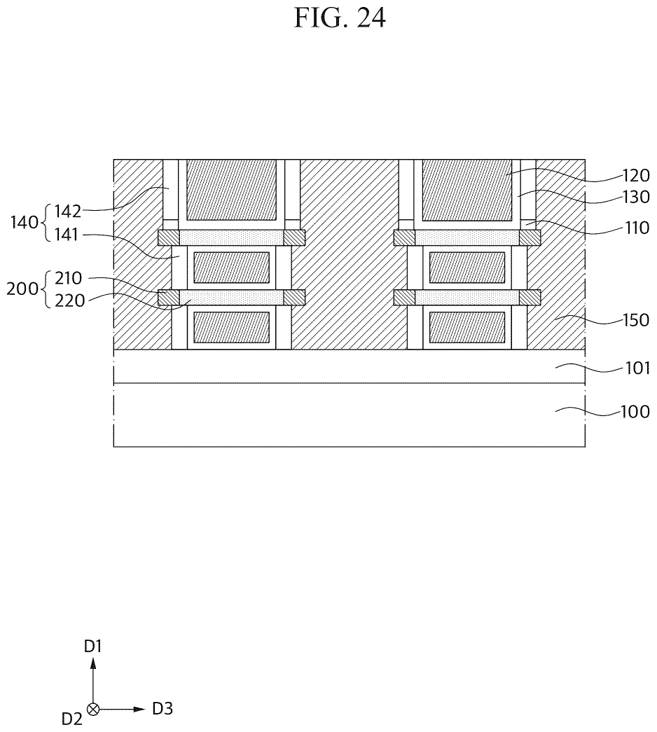

Referring to FIG. 24, the first source/drain pattern 150 may be formed. The first source/drain pattern 150 may be formed between the gate electrodes 120 spaced apart in the third direction D3. The first source/drain pattern 150 may cover at least a portion of the plurality of first active patterns 200. The first source/drain pattern 150 may surround the first contact part 210 protruding further outside than the gate spacer 140. In the process of forming the first source/drain pattern 150, the gate capping layer 125 of FIG. 23 may be removed through a polishing process. Through the polishing process, an upper surface of the gate electrode 120 and the upper surface of the first source/drain pattern 150 may be disposed on the same plane.

Subsequently, referring to FIG. 2, the first gate contact 180 connected to the gate electrode 120 and the first source/drain contact 170 connected to the first source/drain pattern 150 may be formed. The first wiring via 301 and the first wiring layer 311 may be formed above the first gate contact 180 and the first source/drain contact 170.

While various example embodiments of the present disclosure are described in detail above, the scope of the present disclosure is not limited thereto, and it will be apparent to those of ordinary skill in the art that modifications and variations may be made without departing from the scope of the present disclosure as defined by the appended claims. In addition, the aforementioned example embodiments may be implemented with some elements removed, and each example embodiment may be implemented in combination with each other.

According to example embodiments, resistance in a semiconductor device may be reduced.

According to example embodiments, reliability in a semiconductor device may be improved.

What is claimed is:

1. A semiconductor device comprising:
a plurality of active patterns spaced apart in a first direction intersecting with a surface of a substrate;
a gate electrode extending in a second direction intersecting with the first direction and surrounding the plurality of active patterns; and
a source/drain pattern spaced apart from the gate electrode in a third direction intersecting with the first direction and the second direction and connected to the plurality of active patterns in the third direction,
wherein each of the plurality of active patterns comprises:
a contact part, at least a portion of which penetrates into the source/drain pattern; and
a connection part extending from the contact part away from the source/drain pattern in the third direction.

2. The semiconductor device of claim 1, wherein the connection part includes a two-dimensional material.

3. The semiconductor device of claim 1, wherein the connection part and the contact part respectively include a first metal material.

4. The semiconductor device of claim 1, further comprising a gate spacer on a side of the gate electrode in the third direction.

5. The semiconductor device of claim 4, wherein the contact part protrudes farther toward the source/drain pattern than the gate spacer in the third direction.

6. The semiconductor device of claim 4, wherein at least a portion of the contact part overlaps with the gate spacer in the first direction.

7. The semiconductor device of claim 4, wherein a width of the connection part in the third direction is greater than a width between outer side surfaces of the gate spacer in the third direction.

8. The semiconductor device of claim 4, wherein the gate spacer includes:
an inner spacer between the plurality of active patterns and the substrate in the first direction; and
an outer spacer on an uppermost active pattern among the plurality of active patterns in the first direction.

9. The semiconductor device of claim 8, wherein a width between outer side surfaces of the outer spacer in the third direction is greater than a width between outer side surfaces of the inner spacer in the third direction.

10. The semiconductor device of claim 8, further comprising a protective layer between the outer spacer and the uppermost active pattern in the first direction.

11. The semiconductor device of claim 1, wherein, in the third direction, a width of the gate electrode is smaller than a width of the connection part.

12. The semiconductor device of claim 2, wherein the contact part includes a transition metal.

13. The semiconductor device of claim 1, wherein an upper surface of the gate electrode and an upper surface of the source/drain pattern are coplanar.

14. A semiconductor device comprising:
a plurality of active patterns spaced apart in a first direction intersecting with a surface of a substrate;
a gate structure that includes a gate electrode extending in a second direction intersecting with the first direction and surrounding the plurality of active patterns, and a gate spacer on a side of the gate electrode in a third direction intersecting with the first direction and the second direction; and
a source/drain pattern spaced apart from the gate structure in the third direction and connected to the plurality of active patterns in the third direction,
wherein each of the plurality of active patterns protrudes farther toward the source/drain pattern than the gate structure in the third direction and includes a multilayer pattern in the third direction.

15. The semiconductor device of claim 14, wherein the multilayer pattern includes:
a contact part in contact with the source/drain pattern in the third direction; and
a connection part extending from the contact part away from the source/drain pattern in the third direction.

16. The semiconductor device of claim 15, wherein the contact part includes a transition metal, and
wherein the connection part includes a two-dimensional material including a transition metal.

17. The semiconductor device of claim 15, wherein the contact part penetrates into the source/drain pattern.

18. The semiconductor device of claim 14, wherein the gate structure further includes a gate insulating layer on an inner side of the gate spacer in the third direction and surrounding the gate electrode.

19. The semiconductor device of claim 14, further comprising an interlayer insulating layer between the substrate and the gate structure and the source/drain pattern.

20. A semiconductor device comprising:
a plurality of active patterns spaced apart in a first direction intersecting with a surface of a substrate;
a gate structure that includes a gate electrode extending in a second direction intersecting with the first direction and surrounding the plurality of active patterns and a gate spacer on a side of the gate electrode in a third direction intersecting with the first direction and the second direction; and
a source/drain pattern spaced apart from the gate structure in the third direction and connected to the plurality of active patterns in the third direction,
wherein each of the plurality of active patterns comprises:
a contact part in contact with the source/drain pattern in the third direction; and
a connection part extending from the contact part away from the source/drain pattern in the third direction,
wherein the contact part protrudes farther toward the source/drain pattern than the gate structure in the third direction,
wherein the connection part includes a two-dimensional material, and
wherein the contact part and the connection part respectively include a first transition metal.
